(19) United States
(12) Patent Application Publication
(10) Pub. No.: US 2025/0366273 A1
(43) Pub. Date: Nov. 27, 2025

(54) LIGHT-EMITTING DEVICE AND MANUFACTURING METHOD OF LIGHT-EMITTING DEVICE

(71) Applicant: Stanley Electric Co., Ltd., Tokyo (JP)

(72) Inventors: Hirofumi CHIBA, Meguro-ku, Tokyo (JP); Yoshiaki YASUDA, Meguro-ku, Tokyo (JP)

(73) Assignee: Stanley Electric Co., Ltd., Tokyo (JP)

(21) Appl. No.: 19/214,175

(22) Filed: May 21, 2025

(30) Foreign Application Priority Data
May 22, 2024 (JP) 2024-083279

(51) Int. Cl. H10H 20/85; H10H 20/01

(52) U.S. Cl. CPC H10H 20/8508; H10H 20/036

(57) ABSTRACT

A light-emitting device includes a substrate including a first and second substrates of silicon. The first substrate includes insulating films formed on upper and lower surfaces. The second substrate, bonded to the upper surface of the first substrate, has an opening exposing an area on the upper surface. A first thermally-oxidized insulating film is formed in another area on the upper surface. A second, different thermally-oxidized insulating film is in the area. The first substrate has a first and second through-hole groups. The first through-hole group includes through holes penetrating from at a first part of the area to the lower surface. The second through-hole group includes through holes penetrating from a second part of the area to the lower surface. The first upper surface electrode is formed on the first through-hole group. The second upper surface electrode is formed on the second through-hole group.

### CROSS-REFERENCE TO RELATED APPLICATION

The present application is based upon and claims the benefit of priority from the prior Japanese Patent Application No. 2024-083279 filed on May 22, 2024, the entire contents of which are incorporated herein by reference.

### BACKGROUND

### 1. Technical Field

The present invention relates to a light-emitting device and a manufacturing method of the light-emitting device.

### 2. Description of the Related Art

As a light-emitting device that emits ultraviolet rays, a light-emitting device in which a semiconductor light-emitting element, such as a light-emitting diode (LED), is used as a light source has been disclosed. For example, JP-A-2022-040769 discloses a light-emitting device in which a light-emitting element made of aluminum gallium nitride (AlGaN) is placed on a mounting substrate, and the light-emitting element is hermetically sealed on the mounting substrate with a light-transmissive member.

### SUMMARY

In the light-emitting device disclosed in JP-A-2022-040769, a crack may occur on the mounting substrate due to the difference in thermal expansion coefficients between the mounting substrate and electrodes disposed on the mounting substrate, for example, through a temperature rise and fall process during the mounting of the light-emitting element onto the mounting substrate.

For example, if a crack occurs on the mounting substrate, the crack that has occurred grows over the surface exposed to the hermetically sealed space with the light-transmissive member and the surface exposed to the external space. Accordingly, the gas that hermetically seals the light-emitting element leaks, possibly causing gas in external space, that is, the external air, to enter the hermetically sealed space. As a result, for example, a problem, such as early deterioration of the light-emitting element caused by contact with the external air containing moisture, may arise.

The present invention has been made in consideration of the above-described points and an object of which is to provide a light-emitting device that can suppress breaking of the hermetic seal of a light-emitting element and a method thereof.

A light-emitting device according to the present invention includes a substrate structure, a first upper surface electrode, a second upper surface electrode, a light-emitting element, a first lower surface electrode, a second lower surface electrode, and a light-transmissive member. The substrate structure includes a first substrate as a silicon substrate and a second substrate as a silicon substrate. The first substrate includes an insulating film formed on an upper surface and a lower surface. The second substrate is bonded to the upper surface of the first substrate and has an opening that exposes one area on the upper surface of the first substrate. A first insulating film formed in another area as an area other than the one area on the upper surface of the first substrate is a thermally-oxidized film. A second insulating film formed in the one area being an insulating film other than the thermally-oxidized film. The first substrate has a first through-hole group and a second through-hole group. The first through-hole group includes one or a plurality of through holes penetrating from a first part area in the one area to the lower surface of the first substrate. The second through-hole group includes one or a plurality of through holes penetrating from a second part area in the one area to the lower surface of the first substrate. The first upper surface electrode is formed on the first through-hole group in the one area. The second upper surface electrode is formed on the second through-hole group in the one area. The light-emitting element is disposed across the first upper surface electrode and the second upper surface electrode on the one area. The first lower surface electrode is formed on the first through-hole group on the lower surface of the first substrate. The second lower surface electrode is formed on the second through-hole group on the lower surface of the first substrate. The light-transmissive member is bonded to an upper surface of the second substrate and seals a space including the opening. The light-transmissive member is light-transmissive.

A manufacturing method according to the present invention manufactures a light-emitting device including a substrate structure, a first upper surface electrode, a second upper surface electrode, a light-emitting element, a first lower surface electrode, a second lower surface electrode, and a light-transmissive member. The substrate structure includes a first substrate as a silicon substrate and a second substrate as a silicon substrate. The first substrate including an insulating film formed on an upper surface and a lower surface. The second substrate is bonded to the upper surface of the first substrate and has an opening that exposes one area on the upper surface of the first substrate. A first insulating film formed in another area as an area other than the one area on the upper surface of the first substrate is a thermally-oxidized film. A second insulating film formed in the one area is an insulating film other than the thermally-oxidized film. The first substrate has a first through-hole group and a second through-hole group, the first through-hole group including one or a plurality of through holes penetrating from a first part area in the one area to the lower surface of the first substrate. The second through-hole group includes one or a plurality of through holes penetrating from a second part area in the one area to the lower surface of the first substrate. The first upper surface electrode is formed on the first through-hole group in the one area. The second upper surface electrode is formed on the second through-hole group in the one area. The light-emitting element is disposed across the first upper surface electrode and the second upper surface electrode on the one area. The first lower surface electrode is formed on the first through-hole group on the lower surface of the first substrate. The second lower surface electrode is formed on the second through-hole group on the lower surface of the first substrate. The light-transmissive member is bonded to an upper surface of the second substrate and seals a space including the opening. The manufacturing method includes a second insulating film formation step of removing the thermally-oxidized film formed in the one area on the upper surface of the first substrate and forming the second insulating film in the one area where the thermally-oxidized film is removed.

### BRIEF DESCRIPTION OF THE DRAWINGS

FIG. 1 is a top view of a light-emitting device according to Embodiment 1 of the present invention;

FIG. 2 is a cross-sectional view of the light-emitting device according to Embodiment 1 of the present invention;

FIG. 3 is a cross-sectional view of the light-emitting device according to Embodiment 1 of the present invention in one step during manufacturing;

FIG. 4 is a cross-sectional view of the light-emitting device according to Embodiment 1 of the present invention in one step during manufacturing;

FIG. 5 is a cross-sectional view of the light-emitting device according to Embodiment 1 of the present invention in one step during manufacturing;

FIG. 6 is a cross-sectional view of the light-emitting device according to Embodiment 1 of the present invention in one step during manufacturing;

FIG. 7 is a cross-sectional view of the light-emitting device according to Embodiment 1 of the present invention in one step during manufacturing;

FIG. 8 is a cross-sectional view of the light-emitting device according to Embodiment 1 of the present invention in one step during manufacturing;

FIG. 9 is a cross-sectional view of the light-emitting device according to Embodiment 1 of the present invention in one step during manufacturing;

FIG. 10 is a cross-sectional view of the light-emitting device according to Embodiment 1 of the present invention in one step during manufacturing;

FIG. 11 is a cross-sectional view of the light-emitting device according to Embodiment 1 of the present invention in one step during manufacturing;

FIG. 12 is a cross-sectional view of the light-emitting device according to Embodiment 1 of the present invention in one step during manufacturing; and

FIG. 13 is a cross-sectional view of the light-emitting device according to Embodiment 1 of the present invention in one step during manufacturing.

### DETAILED DESCRIPTION

The following describes an embodiment of the present invention in detail. In the following description and attached drawings, same reference numerals are given to actually same or equivalent parts.

### Embodiment 1

### Outline of Light-Emitting Device 100

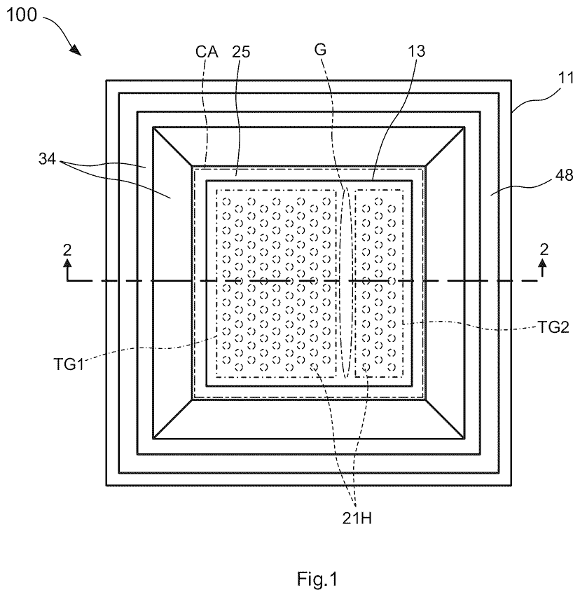

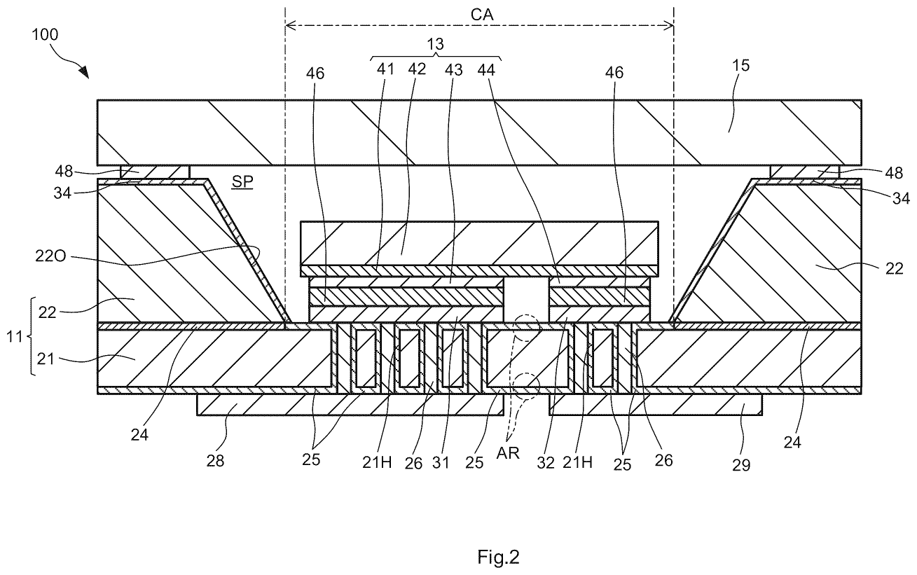

With reference to FIG. 1 and FIG. 2, the configuration of a light-emitting device 100 according to Embodiment 1 is described. FIG. 1 is a top view of the light-emitting device 100 according to Embodiment 1. FIG. 2 is a cross-sectional view taken along the line 2-2 of the light-emitting device 100 illustrated in FIG. 1.

The light-emitting device 100 is configured to include a substrate structure 11, a light-emitting element 13 arranged on the substrate structure 11, and a light-transmissive member 15 that hermetically seals the light-emitting element 13 on the substrate structure 11. In FIG. 1, the light-transmissive member 15 is omitted in order to clearly show the structure and positional relationship of each member. In addition, in FIG. 2, an up-down direction in the drawing is a height direction of the light-emitting device 100, and a left-right direction in the drawing is a width direction of the light-emitting device 100 to give an explanation.

### Substrate Structure 11

First, the configuration of the substrate structure 11 is described. The substrate structure 11 has a flat plate-shaped first substrate 21 having a rectangular upper surface shape and a frame-shaped second substrate 22 formed along an outer edge of an upper surface of the first substrate 21. The second substrate 22 has an opening 22O that exposes an area CA at the center of the upper surface of the first substrate 21 (hereinafter also referred to as a central area CA). In other words, the substrate structure 11 is a recess-shaped structure configured to expose the central area CA of the first substrate 21 by the second substrate 22.

In the substrate structure 11, both the first substrate 21 and the second substrate 22 are silicon substrates made of single-crystal silicon (Si) with the (100) plane as a principal plane. The substrate structure 11 is what is called a silicon-on-insulator (SOI) substrate in which the first substrate 21 and the second substrate 22 are bonded together via a first insulating film 24, which is a buried oxide (BOX) film.

In the SOI substrate, the first insulating film 24 is a thermally-oxidized film made of silicon oxide (SiO₂) formed on the upper surface of the first substrate 21 by performing thermal oxidation treatment on the first substrate 21.

The first substrate 21 has a plurality of through holes 21H, each penetrating the first substrate 21 from the central area CA on the upper surface of the first substrate 21 exposed from the second substrate 22 to a lower surface of the first substrate 21.

As illustrated in FIG. 1, the plurality of through holes 21H are formed to be divided into a first through-hole group TG1 and a second through-hole group TG2. The first through-hole group TG1 is arranged in an area on the left side of the central area CA of the first substrate 21. The second through-hole group TG2 is arranged in an area on the right side of the central area CA to be separated from the first through-hole group TG1. In other words, the first through-hole group TG1 and the second through-hole group TG2 are formed respectively in a first part area and a second part area in the central area CA. The second part area is arranged to form a gap G that extends along the up-down direction in FIG. 1 with respect to the first part area.

In each of the first through-hole group TG1 and the second through-hole group TG2, the respective plurality of through holes 21H are arranged in a regular triangular lattice pattern. In the light-emitting device 100, the spacing between the respective through holes 21H in the first through-hole group TG1 is the same as that in the second through-hole group TG2, and the area where the first through-hole group TG1 is formed is larger than that of the second through-hole group TG2. As a result, the number of through holes 21H in the first through-hole group TG1 is greater than that in the second through-hole group TG2.

As described above, on the first substrate 21, the first insulating film 24 is formed in an area opposed to a lower surface of the second substrate 22 on the upper surface of the first substrate 21, that is, an area overlapping with the second substrate 22 in the top view. In addition, on the first substrate 21, a second insulating film 25 is formed on an internal surface of each of the through holes 21H and the lower surface of the first substrate 21 from the central area CA. That is, on the upper surface of the first substrate 21, the second insulating film 25 is formed in the central area CA, which is one area, and the first insulating film 24 is formed in another area surrounding the central area CA.

In the light-emitting device 100, the second insulating film 25 is made of a material with a fracture toughness value greater than the first insulating film 24 made of SiO₂. Specifically, the second insulating film 25 is made of, for example, silicon nitride (SiN) with a fracture toughness value of 5 MPa·m^{1/2} to 6 MPa·m^{1/2}, which is 10 times or more that of SiO₂ with a fracture toughness value of 0.3 MPa·m^{1/2}.

In the light-emitting device 100, the second insulating film 25 is formed by, for example, a plasma chemical vapor deposition (CVD) method so as to have a film thickness of 0.3 μm. In addition, the second insulating film 25 is controlled so that the film stress, which is a stress that exists within itself, is ±50 MPa or less during the formation process by the plasma CVD method.

The first substrate 21 has columnar through electrodes 26 made of Cu filled inside the respective through holes 21H via the second insulating film 25 so as to penetrate the first substrate 21. That is, the respective through electrodes 26 are exposed from the central area CA on the upper surface of the first substrate 21 and the lower surface of the first substrate 21 while being insulated from one another by the second insulating film 25 formed on the respective internal surfaces of the through holes 21H.

The first substrate 21 has a first lower surface electrode 28 and a second lower surface electrode 29, each having a rectangular upper surface shape. The first lower surface electrode 28 and the second lower surface electrode 29 are formed to be separated from one another on the lower surface of the first substrate 21. The first lower surface electrode 28 is electrically connected to each of the through electrodes 26 arranged in the through holes 21H belonging to the first through-hole group TG1 so as to cover each of the through holes 21H when viewed from a direction perpendicular to the lower surface of the first substrate 21.

In addition, the second lower surface electrode 29 is electrically connected to each of the through electrodes 26 arranged in the through holes 21H belonging to the second through-hole group TG2 so as to cover each of the through holes 21H when viewed from the direction perpendicular to the lower surface of the first substrate 21. That is, the first lower surface electrode 28 and the second lower surface electrode 29 are arranged via the gap G that extends along the up-down direction in FIG. 1.

The first lower surface electrode 28 and the second lower surface electrode 29 are made of titanium (Ti), copper (Cu), nickel (Ni), and gold (Au) stacked from the lower surface side of the first substrate 21 in this order. The first lower surface electrode 28 and the second lower surface electrode 29 function as mounting electrodes when the light-emitting device 100 is mounted on a mounting substrate (not illustrated).

The first substrate 21 has a first upper surface electrode 31 and a second upper surface electrode 32, each having a rectangular upper surface shape. The first upper surface electrode 31 and the second upper surface electrode 32 are formed to be separated from one another in the central area CA on the upper surface of the first substrate 21. The first upper surface electrode 31 is electrically connected to each of the through electrodes 26 arranged in the through holes 21H belonging to the first through-hole group TG1 so as to cover each of the through holes 21H when viewed from a direction perpendicular to the upper surface of the first substrate 21.

In addition, the second upper surface electrode 32 is electrically connected to each of the through electrodes 26 arranged in the through holes 21H belonging to the second through-hole group TG2 so as to cover each of the through holes 21H when viewed from the direction perpendicular to the upper surface of the first substrate 21. That is, the first upper surface electrode 31 and the second upper surface electrode 32 are arranged via the gap G that extends along the up-down direction in FIG. 1.

Therefore, the first upper surface electrode 31 is electrically connected to the first lower surface electrode 28 via each of the through electrodes 26 in the first through-hole group TG1. In addition, the second upper surface electrode 32 is electrically connected to the second lower surface electrode 29 via each of the through electrodes 26 in the second through-hole group TG2. The first upper surface electrode 31 and the second upper surface electrode 32 are made of Ti, Cu, and Ni stacked from the upper surface side of the first substrate 21 in this order.

The Cu film included in each of the first lower surface electrode 28, the second lower surface electrode 29, the first upper surface electrode 31, and the second upper surface electrode 32 described above has a sufficient thickness to release heat generated when the light-emitting element 13 described later is driven to the outside. For example, the Cu film included in each electrode has a thickness of about 20 μm to 30 μm.

The second substrate 22 has an opening 22O that exposes the central area CA on the upper surface of the first substrate 21 as described above. An internal surface of the second substrate 22 that forms the opening 22O is inclined so as to expand toward the upper surface from the lower surface of the second substrate 22. That is, a recessed portion of the substrate structure 11 has a shape in which a frustum of a quadrilateral pyramid is reversed.

In the light-emitting device 100, the internal surface of the second substrate 22 is inclined at an angle of about 54.7° with respect to the upper surface of the first substrate 21. On the internal surface inclined at the angle, the (111) plane of the silicon crystal appears.

The second substrate 22 has a thermally-oxidized film 34 formed over the upper surface and the internal surface. Similarly to the first insulating film 24, the thermally-oxidized film 34 is an insulating film made of SiO₂ formed by performing thermal oxidation treatment on the second substrate 22.

### Light-Emitting Element 13

Next, the configuration of the light-emitting element 13 is described. The light-emitting element 13 is a light-emitting diode with a rectangular upper surface shape that is disposed on the central area CA of the upper surface of the first substrate 21. In other words, the light-emitting element 13 is disposed on a bottom surface of the recessed portion of the substrate structure 11. The light-emitting element 13 is configured to include a semiconductor structure layer 41, a transparent substrate 42, an n-electrode 43, and a p-electrode 44.

The semiconductor structure layer 41 is a semiconductor stacked body composed of an n-type semiconductor layer, a light-emitting layer, and a p-type semiconductor layer (all of which are not illustrated), each containing AlGaN as a main material. When the light-emitting device 100 is driven, the light-emitting layer of the semiconductor structure layer 41 emits light with a wavelength in the deep ultraviolet area, such as light with a wavelength of 100 nm to 280 nm.

The transparent substrate 42 is a flat plate-shaped substrate disposed on the semiconductor structure layer 41. The transparent substrate 42 is made of a material that has translucency to ultraviolet light emitted from the light-emitting layer of the semiconductor structure layer 41, such as aluminum nitride (AlN). In addition, the transparent substrate 42 is also a growth substrate that causes a semiconductor crystal, which becomes the semiconductor structure layer 41 described above, to grow.

The n-electrode 43 and the p-electrode 44 are electrodes plated with Au on Cu, which are connected to the n-type semiconductor layer and the p-type semiconductor layer of the semiconductor structure layer 41, respectively. The n-electrode 43 and the p-electrode 44 are bonded respectively to the first upper surface electrode 31 and the second upper surface electrode 32 described above via a bonding layer 46 made of gold-tin (AuSn). That is, in the light-emitting device 100, the light-emitting element 13 is flip-chip mounted on the first substrate 21 of the substrate structure 11.

The bonding layer 46 is heated, melted, and solidified, thereby bonding the light-emitting element 13 to the first upper surface electrode 31 and the second upper surface electrode 32. The Ni layers constituting the first upper surface electrode 31 and the second upper surface electrode 32 function as barrier layers that suppress diffusive mixing of the Cu layers under the Ni layers and the AuSn constituting the bonding layer 46 when the bonding layer 46 is heated and melted.

### Light-transmissive Member 15

Next, the configuration of the light-transmissive member 15 is described. The light-transmissive member 15 is a plate-shaped body with a rectangular upper surface shape that is bonded to the upper surface of the second substrate 22 via a glass bonding layer 48 made of a paste containing powdered glass frit. The light-transmissive member 15 is made of glass that contains SiO₂ as the main raw material and transmits deep ultraviolet rays emitted from the light-emitting element 13.

In the light-emitting device 100, ultraviolet light emitted from the light-emitting element 13 is made incident on a lower surface of the light-transmissive member 15 and emitted from an upper surface of the light-transmissive member 15. That is, the upper surface of the light-transmissive member 15 functions as a light extraction surface of the light-emitting device 100.

The light-transmissive member 15 is bonded to the upper surface of the second substrate 22 via the glass bonding layer 48, thereby hermetically sealing the light-emitting element 13 arranged in the opening 22O. Specifically, the light-transmissive member 15 and the substrate structure 11 define a space SP (see FIG. 2), which is a housing space. For example, gas that is not altered by ultraviolet light, such as nitrogen (N₂) gas, is enclosed in the space SP and sealed, thereby suppressing the exposure of the light-emitting element 13 to the external air.

Instead of using the glass bonding layer 48, for example, a bonding layer made of AuSn may be used to bond the light-transmissive member 15 to the second substrate 22. In this case, respective metallized layers, in which Ni and Au are stacked in this order, are formed on the lower surface of the light-transmissive member 15 and the upper surface of the second substrate 22, and a layer made of AuSn is arranged between the respective metallized layers formed, thereby bonding the light-transmissive member 15 to the second substrate 22.

### Suppression of Sealing Gas Leakage

Here, using FIG. 1 and FIG. 2, the suppression of leakage of sealing gas that seals the light-emitting element 13 achieved by the light-emitting device 100 of this embodiment is described.

In the light-emitting device 100, the second insulating film 25 formed in the central area CA on the upper surface of the first substrate 21, on the internal surface of each of the through holes 21H, and on the lower surface of the first substrate 21 is made of SiN, which has a greater fracture toughness value than SiO₂ as the first insulating film 24 as described above. Accordingly, in the light-emitting device 100, the occurrence of a brittle fracture in the second insulating film 25 itself can be suppressed, and the growth of a crack from the second insulating film 25 to the first substrate 21 can be suppressed.

In mounting the light-emitting element 13 on the first substrate 21, for example, the light-emitting element 13 is placed on the bonding layer 46 made of AuSn, and the bonding layer 46 is melted by raising the temperature from room temperature to about 260° C. to 320° C. and solidified, thereby bonding the light-emitting element 13 to the first upper surface electrode 31 and the second upper surface electrode 32.

Here, the Cu contained in each of the first lower surface electrode 28, the second lower surface electrode 29, the first upper surface electrode 31, and the second upper surface electrode 32 has a relatively large thermal expansion coefficient, and especially in a temperature zone near the melting point of the bonding layer 46 described above, it expands greatly with increasing temperature. On the other hand, since the Si constituting the first substrate 21 has a smaller thermal expansion coefficient than Cu, the degree of expansion of Si is smaller than that of Cu under the same temperature.

Since this situation happens in mounting the light-emitting element 13, each of the first lower surface electrode 28, the second lower surface electrode 29, the first upper surface electrode 31, and the second upper surface electrode 32 expands and shrinks, causing thermal stress to the first substrate 21.

Specifically, for example, on the lower surface side of the first substrate 21, a tensile stress by the first lower surface electrode 28 and the second lower surface electrode 29 attempting to pull the first substrate 21 in opposite directions from one another is generated when the thermally expanded first lower surface electrode 28 and second lower surface electrode 29 shrink during temperature decrease. On the upper surface side of the first substrate 21, a tensile stress by the first upper surface electrode 31 and the second upper surface electrode 32 attempting to pull the first substrate 21 in the opposite directions from one another is generated when the thermally expanded first upper surface electrode 31 and second upper surface electrode 32 shrink during temperature decrease.

When such tensile stresses are generated on the first substrate 21, a large force is likely to be applied to, for example, areas AR enclosed and indicated by two-dot chain lines in FIG. 2, that is, an area between the first lower surface electrode 28 and the second lower surface electrode 29 and an area between the first upper surface electrode 31 and the second upper surface electrode 32.

For example, if the first insulating film 24 made of SiO₂ is formed over the upper surface and the lower surface of the first substrate 21, the fracture toughness value of SiO₂ is relatively small at 0.3 MPa·m^{1/2}. Accordingly, a brittle fracture occurs in the areas AR by being subject to the tensile stresses described above, causing a crack in the first insulating film 24. The crack that has occurred grows, for example, in the gap G between the first through-hole group TG1 and the second through-hole group TG2 in FIG. 1 along the up-down direction in the drawing.

A crack easily propagates from the first insulating film 24, which is a thermally-oxidized film formed by performing thermal oxidation treatment on Si, to the first substrate 21 made of Si. Therefore, for example, if cracks occur on the first insulating film 24 in the above-described areas AR, the cracks that have occurred grow so as to penetrate the first substrate 21 and may eventually connect to one another.

In addition, even if a crack occurs only in one of the areas AR in FIG. 2, it may eventually penetrate the first substrate 21 as the crack that has occurred grows from one side to the other.

For example, when a crack penetrates the first substrate 21, the gas that hermetically seals the light-emitting element 13 may leak outside. If such a situation occurs, there is a risk that the light-emitting element 13 will deteriorate early due to external air containing outside moisture and the like entering the space SP of the substrate structure 11.

In the light-emitting device 100 of this embodiment, the second insulating film 25 made of SiN with a greater fracture toughness value than SiO₂, specifically 10 times or more the fracture toughness value of SiO₂, is formed in the central area CA on the upper surface of the first substrate 21, on the internal surface of each of the through holes 21H, and on the lower surface of the first substrate 21, as described above. That is, the second insulating film 25 is less susceptible to a brittle fracture when stress occurs on the second insulating film 25.

Therefore, with the light-emitting device 100 of this embodiment, even if thermal stress is applied to the first substrate 21 due to the thermal expansion of Cu contained in each of the first lower surface electrode 28, the second lower surface electrode 29, the first upper surface electrode 31, and the second upper surface electrode 32 in mounting the light-emitting element 13 to the first substrate 21, the growth of a crack to the first substrate 21 can be suppressed by using the second insulating film 25 with a relatively large fracture toughness value.

Therefore, the light-emitting device 100 of this embodiment can suppress the leakage of the sealing gas caused by the breaking of the hermetic seal of the light-emitting element 13 and the exposure of the light-emitting element 13 to the external air containing moisture.

In the light-emitting device 100 of this embodiment, the second insulating film 25 is formed in the central area CA on the upper surface of the first substrate 21, on the internal surfaces of the through holes 21H, and on the lower surface of the first substrate 21, but this should not be construed in a limiting sense. It is only necessary to form the second insulating film 25 at least in the central area CA on the upper surface of the first substrate 21. Therefore, an insulating film other than the second insulating film 25, such as the first insulating film 24, may be formed on the internal surface of each of the through holes 21H and the lower surface of the first substrate 21.

Even in such a case, even if a crack occurs from the lower surface side of the first substrate 21, that is, on the first insulating film 24, and it grows toward the upper surface side, the second insulating film 25 can suppress the growth of the crack, therefore suppressing the breaking of the hermetic seal of the light-emitting element 13.

In addition, in the light-emitting device 100 of this embodiment, SiN with a greater fracture toughness value than SiO₂ (the first insulating film 24) is used for the second insulating film 25, but this should not be construed in a limiting sense. Other materials may be used for the second insulating film 25.

For example, zirconium oxide (ZrO₂), aluminum oxide (Al₂O₃), or silicon carbide (SiC) may be used instead of SiN for the second insulating film 25. The fracture toughness value of ZrO₂ is approximately 7 MPa·m^{1/2} to 8 MPa·m^{1/2}, and the fracture toughness value of Al₂O₃ and SiC is approximately 3 MPa·m^{1/2} to 4 MPa·m^{1/2}.

In the light-emitting device 100 of this embodiment, the second insulating film 25 made of SiN with a greater fracture toughness value than the first insulating film 24 made of SiO₂ is formed in the central area CA on the upper surface of the first substrate 21, on the internal surfaces of the through holes 21H, and on the lower surface of the first substrate 21. However, a new film formation may be simply performed regardless of the fracture toughness value.

For example, instead of the first insulating film 24 as a thermally-oxidized film, an insulating film made of SiO₂ formed by, for example, the plasma CVD method may be formed. That is, even with the same SiO₂, the original thermally-oxidized film may be peeled off, and a new film formation may be performed by a method other than the thermal oxidation treatment.

The insulating film, thus newly formed, has a lower degree of bonding (adhesion) with respect to the first substrate 21 than the thermally-oxidized film. Therefore, even if a crack occurs on the insulating film, the crack is difficult to propagate to the first substrate 21. Accordingly, the effect of suppressing crack growth can be expected compared with the case where the first insulating film 24 as a thermally-oxidized film is formed on the first substrate 21.

In the light-emitting device 100 of this embodiment, a plurality of through holes 21H are formed in each of the first through-hole group TG1 and the second through-hole group TG2 in the first substrate 21, but this should not be construed in a limiting sense. The number of the through holes 21H may be one in each through-hole group. At this time, a larger diameter may be set for one through hole 21H.

### Verification

Here, the verification conducted for the light-emitting device 100 of this embodiment and the results of the verification are described. In this verification, a 2.6 mm square silicon substrate simulating the first substrate 21 was prepared. An insulating film with a thickness of 0.3 μm was formed over the upper surface and the lower surface of the prepared silicon substrate. Two Cu electrodes, each having a thickness of 25 μm, were formed only on the lower surface side of the silicon substrate to be separated from one another. The one produced as described above was used as a sample.

In this verification, a sample in which the insulating film of the silicon substrate prepared as described above was a SiN film was used as a first sample. A sample in which the insulating film was a SiO₂ film was used as a second sample that was a comparative example. That is, only the material constitution of the insulating film differs between the first sample and the second sample.

In this verification, 27 samples were prepared for each of the first sample and the second sample described above. Each sample was placed on a hot plate heated to 260° C. for two minutes. Afterward, the sample was placed on a heat sink and cooled rapidly, and then, the presence/absence of a crack in the insulating film and the silicon substrate was checked using an optical microscope.

Table 1 shows the number of samples in which a crack occurred in the first sample and the second sample in this verification. From the results shown in Table 1, no cracks were confirmed in all 27 samples in the first sample. On the other hand, in the second sample as a comparative example, cracks were confirmed in 15 out of 27 samples.

TABLE 1

| | The number of samples |
|---|---|
| Sample | in which cracks occurred |
| First Sample (Present Invention) | 0/27 |
| Second Sample (Comparative Example) | 15/27 |

The above results show that by adopting a SiN film, which has a greater fracture toughness value than SiO₂, instead of a SiO₂ film, as the insulating film formed on the silicon substrate, cracks are less likely to occur in the samples. Therefore, by forming the second insulating film 25 made of SiN on the first substrate 21, as in the light-emitting device 100, for example, the occurrence of cracks in the first substrate 21 can be suppressed when the light-emitting element 13 is mounted.

Although not illustrated, as a result of checking the presence/absence of a crack in the above verification by changing the thickness of the SiN film formed on the silicon substrate, it was found that no cracks occurred in the samples by setting the film thickness of the SiN film to about 0.3 μm to 2.0 μm.

### Manufacturing Method of Light-Emitting Device

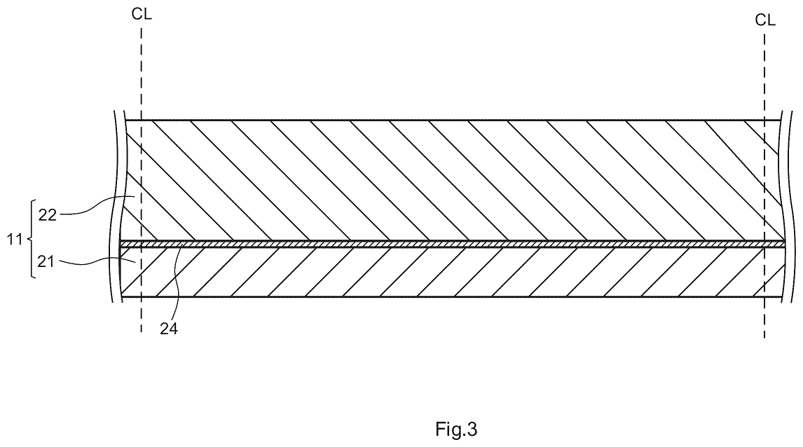

Next, using FIG. 3 to FIG. 13, the manufacturing method of the light-emitting device 100 according to Embodiment 1 of this application is described. Each of FIG. 3 to FIG. 13 is a cross-sectional view of the light-emitting device 100 in one step during manufacturing. In each of FIG. 3 to FIG. 13, the cross-sectional view taken along the line 2-2 illustrated in FIG. 1 is used for explanation, similarly to FIG. 2.

In this embodiment, the light-emitting device 100 is manufactured in a wafer level package (WLP) form, in which a respective plurality of light-emitting devices 100 are collectively manufactured on a wafer-like substrate structure 11 and the light-emitting devices 100 are individualized by dicing after the manufacturing. In each of FIG. 3 to FIG. 13, split lines CL, which are split lines for individualizing the light-emitting devices 100 by dicing, are indicated.

First, as illustrated in FIG. 3, the substrate structure 11, in which the first substrate 21 made of single-crystal Si and the second substrate 22 made of single-crystal Si are bonded together, is prepared. On the first substrate 21, the first insulating film 24 as a buried oxide film made of SiO₂ is formed over the upper surface (Step S1: substrate structure preparation step). While SiO₂ films, which are natural oxide films, are formed on the lower surface of the first substrate 21 and the upper surface of the second substrate 22, the natural oxide films are not illustrated in this explanation.

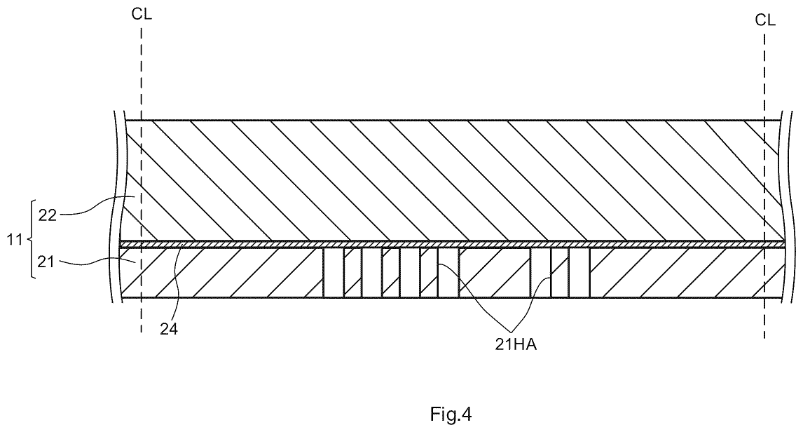

Next, as illustrated in FIG. 4, etching is performed from the lower surface side of the first substrate 21 to form a plurality of columnar hole portions 21HA, which become a plurality of through holes 21H in a step described later (Step S2: hole portion formation step). Each of the plurality of hole portions 21HA is formed using deep reactive ion etching (DRIE), for example, by the Bosch process. In the formation of the plurality of hole portions 21HA, the first insulating film 24 functions as an etching stop layer.

Although not illustrated, this step includes a step of applying photoresist to the lower surface of the first substrate 21 and a step of removing the photoresist after etching for the formation of the plurality of hole portions 21HA.

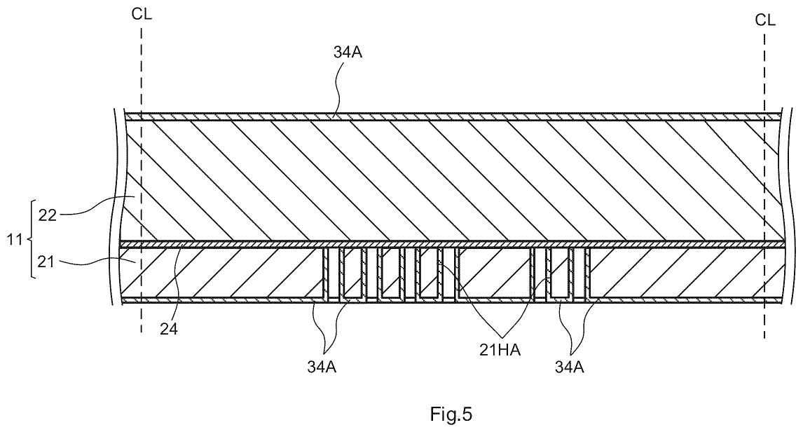

Next, as illustrated in FIG. 5, a thermally-oxidized film 34A made of SiO₂ is formed from the lower surface of the first substrate 21 to the internal surface of each of the hole portions 21HA and over the upper surface of the second substrate 22 by wet thermal oxidation in which heating is performed at 1100° C. under a water-vapor atmosphere for seven hours or more (Step S3: thermally-oxidized film formation step). The thermally-oxidized film 34A formed in this step forms an etching stop layer on the internal surfaces of the hole portions 21HA when etching is performed in the next step.

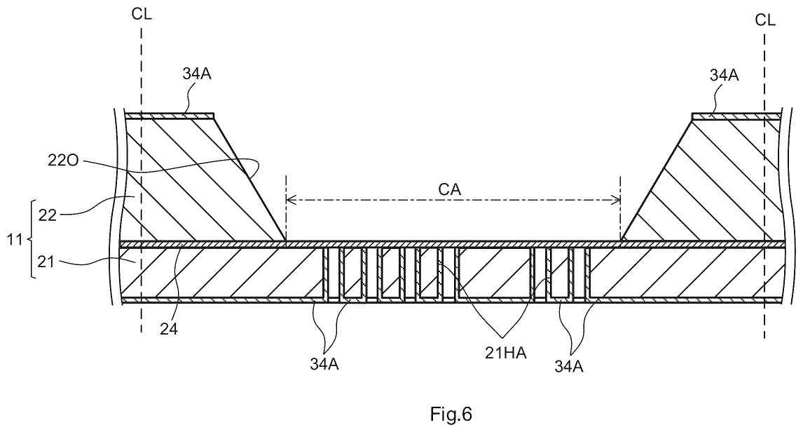

Next, as illustrated in FIG. 6, wet etching using a tetramethylammonium hydroxide (TMAH) water solution is performed until the first insulating film 24 formed on the upper surface of the first substrate 21 is exposed from the upper surface of the second substrate 22 to form the opening 22O (Step S4: opening formation process). That is, a recessed portion is formed in the substrate structure 11. In the formation of the opening 22O, the first insulating film 24 functions as an etching stop layer.

In this step, so-called crystal anisotropic etching is performed using the difference in etching rate depending on the crystal plane of Si. Accordingly, the (111) plane appears on the internal surface of the second substrate 22 as the etching proceeds. The (111) plane is less easily etched than the (100) plane, that is, it has a slower etching rate.

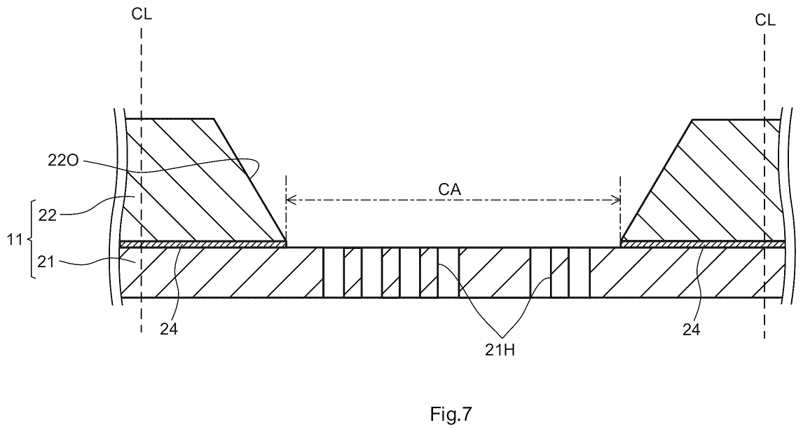

Next, as illustrated in FIG. 7, the thermally-oxidized film 34A and the first insulating film 24 exposed to the central area CA on the upper surface of the first substrate 21 are removed with buffered hydrofluoric acid (BHF) (Step S5: oxidized film removing step). Accordingly, the first insulating film 24 exposed to the central area CA on the upper surface of the first substrate 21 is removed, allowing each of the plurality of hole portions 21HA formed in Step S2 to communicate with the central area CA and forming the plurality of through holes 21H. In addition, by this step, the first insulating film 24 remains only in a peripheral area surrounding the central area CA on the upper surface of the first substrate 21.

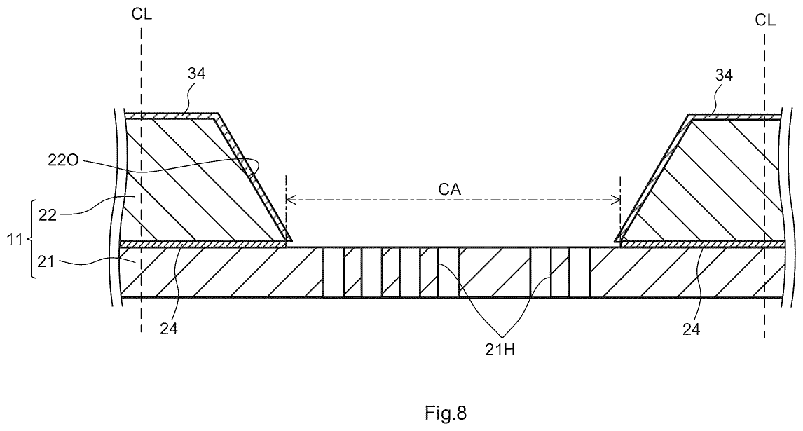

Next, as illustrated in FIG. 8, the thermally-oxidized film 34 is formed on the upper surface and the internal surface of the second substrate 22 (Step S6: thermally-oxidized film formation step). For example, the thermally-oxidized film 34 is formed by wet thermal oxidation in which heating is performed at 1100° C. in a water-vapor atmosphere for seven hours or more while masking the central area CA on the upper surface of the first substrate 21 and the lower surface of the first substrate 21.

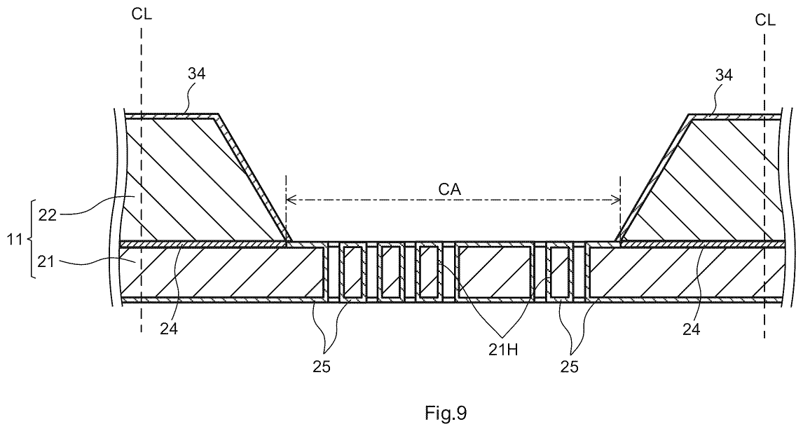

Next, as illustrated in FIG. 9, the second insulating film 25 is formed in the central area CA on the upper surface of the first substrate 21, on the internal surface of each of the through holes 21H, and on the lower surface of the first substrate 21 (Step S7: second insulating film formation step). The second insulating film 25 is formed, for example, with a predetermined film thickness by the plasma CVD method while masking the upper surface and the internal surface of the second substrate 22.

The second insulating film 25 may be formed by a film formation method, such as a low pressure (LP)-CVD method and atomic layer deposition (ALD), instead of the plasma CVD method.

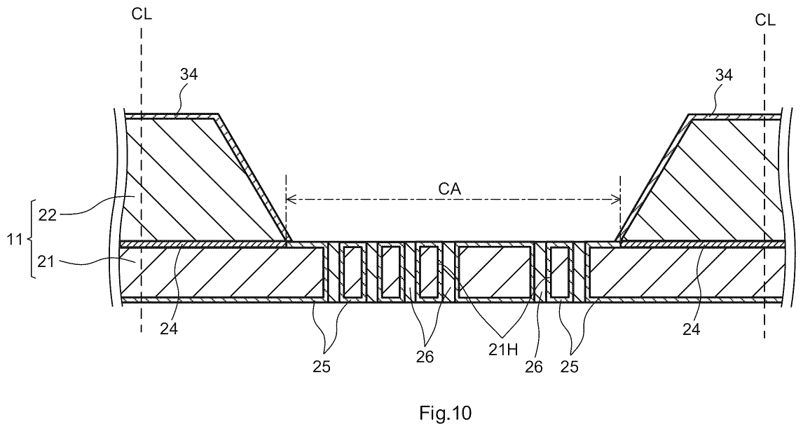

Next, as illustrated in FIG. 10, each of a plurality of through electrodes 26 made of Cu is formed inside each of the plurality of through holes 21H (Step S8: through electrode formation step). For example, the through electrode 26 is formed by forming a seed layer (not illustrated) with Ti and Cu stacked in this order on the lower surface of the first substrate 21 and on part of the internal surface of the through hole 21H, masking the lower surface of the first substrate 21, and then filling Cu on the seed layer from the lower surface to the upper surface of the first substrate 21 by electrolytic plating.

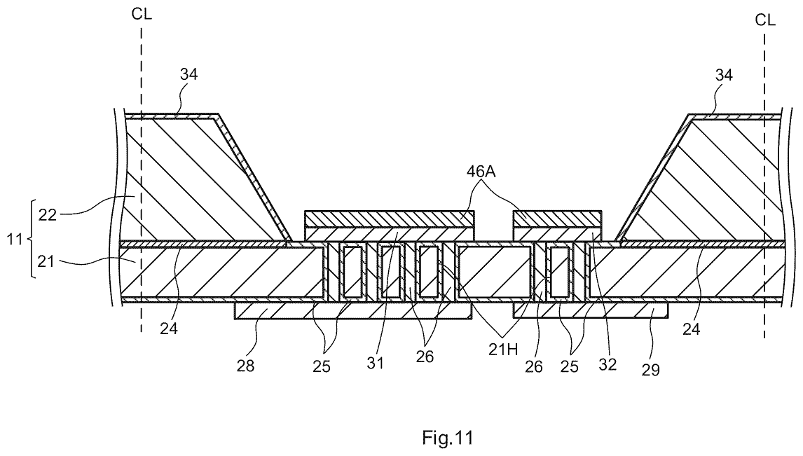

Next, as illustrated in FIG. 11, the first upper surface electrode 31 and the second upper surface electrode 32 are formed in the central area CA on the upper surface of the first substrate 21. The first lower surface electrode 28 and the second lower surface electrode 29 are formed on the lower surface of the first substrate 21. An AuSn layer 46A that becomes the base material of the bonding layer 46 is formed on the first upper surface electrode 31 and the second upper surface electrode 32 (Step S9: electrode formation step).

In Step S9, a seed layer (not illustrated) with Ti and Cu stacked in this order is formed over the central area CA on the upper surface of the first substrate 21 by sputter deposition. After sections excluding the respective upper surface electrodes are masked with a resist, Cu/Ni layers and the AuSn layer 46A are each stacked by electrolytic plating. Afterward, by removing the resist used for masking and etching the remaining seed layer, the first upper surface electrode 31, the second upper surface electrode 32, and the AuSn layer 46A are formed.

Further, in Step S9, the first lower surface electrode 28 and the second lower surface electrode 29 are formed by masking sections excluding the respective lower surface electrodes on the lower surface of the first substrate 21 with a resist and then stacking Ni and Au in this order by electrolytic plating.

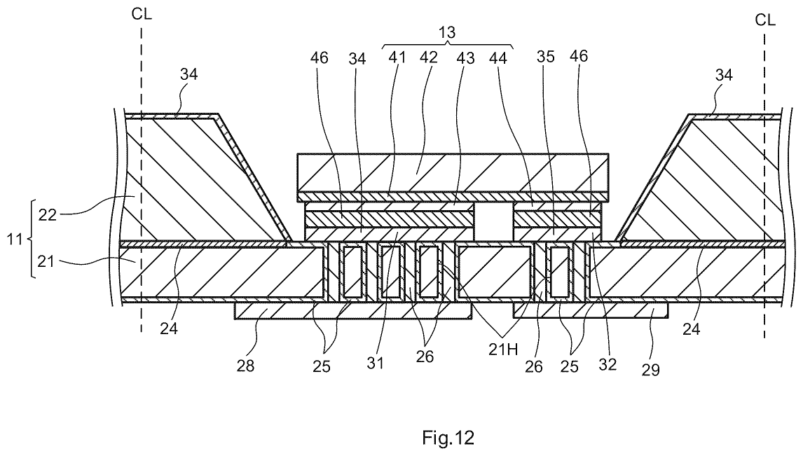

Next, as illustrated in FIG. 12, the light-emitting element 13 is mounted in the central area CA on the upper surface of the first substrate 21 (Step S10: element mounting step). For example, the light-emitting element 13 is mounted by heating the substrate structure 11 on which the light-emitting element 13 is placed at 340° C. for 30 seconds under a nitrogen (N₂) atmosphere and performing eutectic bonding of the Au layers formed on the surfaces of the n-electrode 43 and the p-electrode 44 and the AuSn layer 46A.

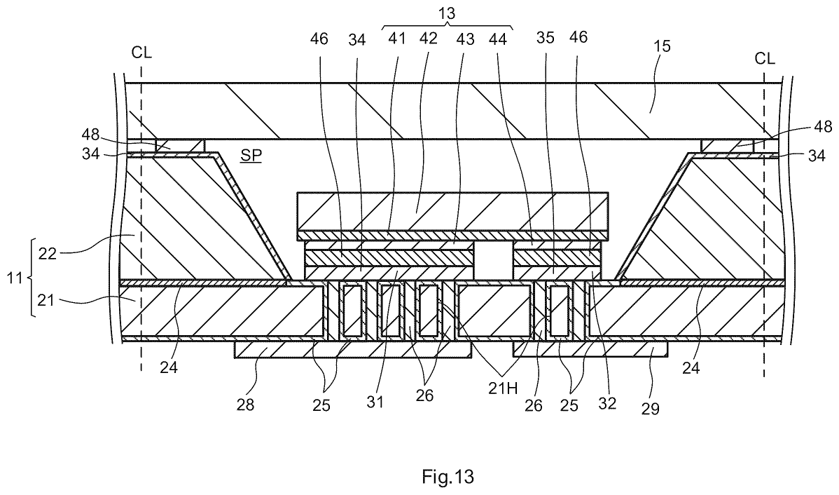

Next, as illustrated in FIG. 13, the light-transmissive member 15 is bonded to the upper surface of the second substrate 22 (Step S11: light-transmissive member bonding step). In this step, the glass bonding layer 48 is formed in advance on the light-transmissive member 15, and the light-transmissive member 15 on which the glass bonding layer 48 is formed is arranged to cover the opening 22O.

In this step, the glass bonding layer 48 is applied over the lower surface of the light-transmissive member 15 in a position corresponding to the upper surface of the second substrate 22 so as to surround the opening 22O and have a size that does not overlap the split lines CL of the substrate structure 11.

Afterward, the light-transmissive member 15 is bonded to the upper surface of the second substrate 22 by irradiating the glass bonding layer 48 through the light-transmissive member 15 placed on the upper surface of the second substrate 22 with laser light having near-infrared wavelength under an N₂ atmosphere and locally heating and melting the glass bonding layer 48. At this time, the molten glass bonding layer 48 and the thermally-oxidized film 34 formed on the upper surface of the second substrate 22 mutually diffuse to form an interdiffusion layer (not illustrated). Accordingly, the opening 22O is filled with N₂, which is an inert gas, and the hermetically sealed space SP is formed.

The laser light emitted to the glass bonding layer 48 is scanned along the upper surface shape of the second substrate 22. The scanning time of the laser light is about two to three seconds per light-emitting device 100. Therefore, in each light-emitting device 100, the glass bonding layer 48 is heated locally and in a short time by the laser light. This can avoid remelting the bonding layer made of AuSn that bonds the light-emitting element 13 caused by overheating it.

In conventional light-emitting devices, a hermetic seal has been performed using eutectic bonding with AuSn for two times of bonding, which are bonding of a light-emitting element and bonding of a light-transmissive member to an AlN substrate. In this case, during the second AuSn eutectic bonding by bonding the light-transmissive member, there has been a possibility that the bonding layer 46 that bonds the light-emitting element remelts, causing a manufacturing failure, such as misalignment of the light-emitting element placement position.

In the manufacturing method of the light-emitting device 100 of this embodiment, a hermetic seal is performed by heating the glass bonding layer 48 locally and in a short time using laser light as described above. Accordingly, remelting of the bonding layer 46 that bonds the light-emitting element 13 can be avoided, suppressing the occurrence of a manufacturing failure, such as misalignment of the light-emitting element placement position.

Lastly, the substrate structure 11 with the light-transmissive member 15 bonded is set in a dicing machine, and the light-transmissive member 15 and the substrate structure 11 are cut along the split lines CL to individualize the light-emitting device 100 (Step S12: individualization step). By the above steps, the light-emitting device 100 as illustrated in FIG. 2 can be obtained.

As described above, the light-emitting device 100 of this embodiment can be manufactured as a wafer level package in which the light-emitting devices 100 are formed in a lattice pattern on silicon wafers. Conventionally, since it was necessary to use an individual substrate made of AlN and hermetically seal the substrate one by one, there were drawbacks in the takt time and cost during manufacturing.

In the manufacturing method of the light-emitting device 100 of this embodiment, a plurality of light-emitting devices 100 can be manufactured at once by setting the substrate structure 11 with the light-transmissive member 15 bonded in a dicing machine and cutting them. Therefore, it is possible to achieve a reduction in the takt time and cost during manufacturing.

It is understood that the foregoing description and accompanying drawings set forth the preferred embodiments of the present invention at the present time. Various modifications, additions and alternative designs will, of course, become apparent to those skilled in the art in light of the foregoing teachings without departing from the spirit and scope of the disclosed invention. Thus, it should be appreciated that the present invention is not limited to the disclosed Examples but may be practiced within the full scope of the appended claims. The present application is based upon and claims the benefit of priority from the prior Japanese Patent Application No. 2024-83279 filed on May 22, 2024, the entire contents of which are incorporated herein by reference.

### DESCRIPTION OF REFERENCE SIGNS

100 Light-emitting device
11 Substrate structure
13 Light-emitting element
15 Light-transmissive member
21 First substrate
22 Second substrate
24 First insulating film
25 Second insulating film
26 Through electrode
28 First lower surface electrode
29 Second lower surface electrode
31 First upper surface electrode
32 Second upper surface electrode
34 Thermally-oxidized film
41 Semiconductor structure layer
42 Transparent substrate
43 n-electrode
44 p-electrode
46 Bonding layer
48 Glass bonding layer

What is claimed is:

1. A light-emitting device comprising:
a substrate structure that includes a first substrate as a silicon substrate and a second substrate as a silicon substrate, the first substrate including an insulating film formed on an upper surface and a lower surface, the second substrate being bonded to the upper surface of the first substrate and having an opening that exposes one area on the upper surface of the first substrate, a first insulating film formed in another area as an area other than the one area on the upper surface of the first substrate being a thermally-oxidized film, a second insulating film formed in the one area being an insulating film other than the thermally-oxidized film, the first substrate having a first through-hole group and a second through-hole group, the first through-hole group including one or a plurality of through holes penetrating from a first part area in the one area to the lower surface of the first substrate, the second through-hole group including one or a plurality of through holes penetrating from a second part area in the one area to the lower surface of the first substrate;
a first upper surface electrode formed on the first through-hole group in the one area;
a second upper surface electrode formed on the second through-hole group in the one area;
a light-emitting element disposed across the first upper surface electrode and the second upper surface electrode on the one area;
a first lower surface electrode formed on the first through-hole group on the lower surface of the first substrate;
a second lower surface electrode formed on the second through-hole group on the lower surface of the first substrate; and
a light-transmissive member bonded to an upper surface of the second substrate and sealing a space including the opening, the light-transmissive member being light-transmissive.

2. The light-emitting device according to claim 1, wherein
the second insulating film has a greater fracture toughness value than the first insulating film.

3. The light-emitting device according to claim 2, wherein
the second insulating film is made of any one of silicon nitride, zirconium oxide, aluminum oxide, or silicon carbide.

4. The light-emitting device according to claim 1, wherein
the second insulating film is formed on an internal surface of the one or each of the plurality of through holes in the first through-hole group and the second through-hole group, and a through electrode penetrating the first substrate is formed inside the one or each of the plurality of through holes on which the second insulating film is formed.

5. The light-emitting device according to claim 2, wherein
the insulating film formed on the lower surface of the first substrate is the second insulating film.

6. The light-emitting device according to claim 1, wherein
the second substrate has the thermally-oxidized film formed on an upper surface thereof, and
the light-transmissive member is bonded to the upper surface of the second substrate via the thermally-oxidized film and a glass bonding layer made of glass frit arranged on the thermally-oxidized film.

7. The light-emitting device according to claim 1, wherein
an internal surface of the second substrate forming the opening is a (111) plane of the silicon crystal.

8. The light-emitting device according to claim 1, wherein
the one or the respective plurality of through holes belonging to the first through-hole group and the second through-hole group are formed in a triangular lattice pattern.

9. A manufacturing method of a light-emitting device, wherein
the light-emitting device includes:
a substrate structure that includes a first substrate as a silicon substrate and a second substrate as a silicon substrate, the first substrate including an insulating film formed on an upper surface and a lower surface, the second substrate being bonded to the upper surface of the first substrate and having an opening that exposes one area on the upper surface of the first substrate, a first insulating film formed in another area as an area other than the one area on the upper surface of the first substrate being a thermally-oxidized film, a second insulating film formed in the one area being an insulating film other than the thermally-oxidized film, the first substrate having a first through-hole group and a second through-hole group, the first through-hole group including one or a plurality of through holes penetrating from a first part area in the one area to the lower surface of the first substrate, the second through-hole group including one or a plurality of through holes penetrating from a second part area in the one area to the lower surface of the first substrate;
a first upper surface electrode formed on the first through-hole group in the one area;
a second upper surface electrode formed on the second through-hole group in the one area;
a light-emitting element disposed across the first upper surface electrode and the second upper surface electrode on the one area;
a first lower surface electrode formed on the first through-hole group on the lower surface of the first substrate;
a second lower surface electrode formed on the second through-hole group on the lower surface of the first substrate; and
a light-transmissive member bonded to an upper surface of the second substrate and sealing a space including the opening, wherein
the manufacturing method comprises a second insulating film formation step of removing the thermally-oxidized film formed in the one area on the upper surface of the first substrate and forming the second insulating film in the one area where the thermally-oxidized film is removed.
